(19) United States
(12) Patent Application Publication
(10) Pub. No.: US 2026/0269792 A1
(43) Pub. Date: Sep. 10, 2026

(54) AMPLIFIER CIRCUIT

(71) Applicant: SUMITOMO ELECTRIC DEVICE INNOVATIONS, INC., Kanagawa (JP)

(72) Inventor: Seiya TAKASHIMA, Osaka (JP)

(21) Appl. No.: 19/542,022

(22) Filed: Feb. 17, 2026

(30) Foreign Application Priority Data
Mar. 6, 2025 (JP) 2025-035771

(51) Int. Cl. H03F 1/56; H10W 44/20

(52) U.S. Cl. CPC H03F 1/565; H10W 44/206; H10W 44/234; H10W 44/241; H03F 2200/451

(57) ABSTRACT

An amplifier circuit includes an input terminal to which a high frequency signal is to be input, an amplifier configured to amplify the high frequency signal, an output terminal configured to output the high frequency signal amplified by the amplifier, and a matching circuit including a first inductor and a first capacitor connected in parallel between the input terminal and the amplifier or between the amplifier and the output terminal. A resonance frequency of the first inductor with the first capacitor is 1.9 times or less of a center frequency of an operating band in the amplifier.

### CROSS REFERENCE TO RELATED APPLICATIONS

This application claims priority to Japanese Patent Application No. 2025-035771 filed on Mar. 6, 2025, and the entire contents of the Japanese patent application are incorporated herein by reference.

### TECHNICAL FIELD

The present disclosure relates to an amplifier circuit.

### BACKGROUND

An amplifier circuit is provided with a matching circuit for matching the impedance of an amplifier with that of an input terminal or an output terminal. It is known to provide a resonant circuit having an inductor and a capacitor connected in parallel in a signal path of the matching circuit, and to set a resonance frequency of the resonant circuit to a second harmonic of an operation frequency or within a predetermined range around the second harmonic (see Patent Literature 1: Japanese Unexamined Patent Application Publication No. 2009-232076).

### SUMMARY

An embodiment of the present disclosure is an amplifier circuit that includes an input terminal to which a high frequency signal is configured to be input, an amplifier configured to amplify the high frequency signal, an output terminal configured to output the high frequency signal amplified by the amplifier, and a matching circuit including a first inductor and a first capacitor connected in parallel between the input terminal and the amplifier or between the amplifier and the output terminal. A resonance frequency of the first inductor with the first capacitor is 1.9 times or less of a center frequency of an operating band of the amplifier.

### BRIEF DESCRIPTION OF THE DRAWINGS

FIG. 1 is a circuit diagram of an amplifier circuit according to a first embodiment.

FIG. 2 is a circuit diagram of an amplifier circuit according to a comparative example.

FIG. 3 is an equivalent circuit of impedance Zin of the amplifier.

FIG. 4 is a Smith chart showing the impedance Zin.

FIG. 5 is a Smith chart illustrating impedance matching by a matching circuit.

FIG. 6 is a diagram showing L1′/L1 with respect to m.

FIG. 7 is a circuit diagram of the amplifier circuit according to a second embodiment.

FIG. 8 is a plan view of the amplifier circuit according to the second embodiment.

FIG. 9 is an A-A cross-sectional view of FIG. 8.

FIG. 10 shows S21 with respect to frequency in a simulation.

FIG. 11 is a schematic diagram showing bandwidth with respect to m.

### DETAILED DESCRIPTION

When a control circuit matches the impedance of an amplifier with the impedance of an input terminal or an output terminal, inductance of an inductor in a signal path may increase. Since an inductor having a large inductance is increased in size, the amplifier circuit is increased in size.

An object of the present disclosure is to provide an amplifier circuit that can be downsized.

### DESCRIPTION OF EMBODIMENTS OF PRESENT DISCLOSURE

First, embodiments of the present disclosure will be listed and described.

(1) An embodiment of the present disclosure is an amplifier circuit that includes an input terminal to which a high frequency signal is to be input, an amplifier configured to amplify the high frequency signal, an output terminal configured to output the high frequency signal amplified by the amplifier, and a matching circuit including a first inductor and a first capacitor connected in parallel between the input terminal and the amplifier or between the amplifier and the output terminal. A resonance frequency of the first inductor with the first capacitor is 1.9 times or less of a center frequency of an operating band of the amplifier. This allows the first inductor to be downsized, thereby allowing the amplifier circuit to be downsized.

(2) In the above (1), the resonance frequency may be 1.1 times or more of the center frequency. This allows the bandwidth to be increased.

(3) In the above (1) or (2), the resonance frequency may be 1.6 times or less of the center frequency. This enables the amplifier circuit to be downsized.

(4) In any one of the above (1) to (3), the matching circuit may be electrically connected between the input terminal and the amplifier. This enables the amplifier circuit to be downsized.

(5) In the above (4), the amplifier circuit may further include a second capacitor shunt-connected to a node between the input terminal and a circuit including the first inductor and the first capacitor. Thus, the impedance can be converted.

(6) In any one of the above (1) to (5), the first inductor may include a first bonding wire having a first end electrically connected to a first end of the first capacitor and a second end electrically connected to a second end of the first capacitor. This enables the amplifier circuit to be downsized.

(7) In the above (6), the amplifier circuit may further include a base, and a passive component mounted on the base and including the first capacitor, a first pad, and a second pad, the first pad being electrically connected to a first end of the first capacitor, the second pad being electrically connected to a second end of the first capacitor. The first end of the first bonding wire may be bonded to the first pad, and the second end of the first bonding wire may be bonded to the second pad. This allows the planar size to be reduced.

(8) In the above (7), the amplifier circuit may further include a semiconductor chip mounted on the base and including the amplifier and a third pad electrically connected to the amplifier, and a second bonding wire having a first end electrically connected to the second pad and a second end electrically connected to the third pad. This allows the amplifier to be electrically connected to the first inductor and the first capacitor.

(9) In the above (7) or (8), the passive component may have a second capacitor shunt-connected to the first pad. This allows the planar size to be reduced.

(10) In any one of the above (1) to (9), the amplifier may have a transistor. The first inductor and the first capacitor may be connected in parallel between the input terminal and a gate of the transistor. This enables the amplifier circuit to be downsized.

### DETAILS OF EMBODIMENTS OF PRESENT DISCLOSURE

Specific examples of an amplifier circuit according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

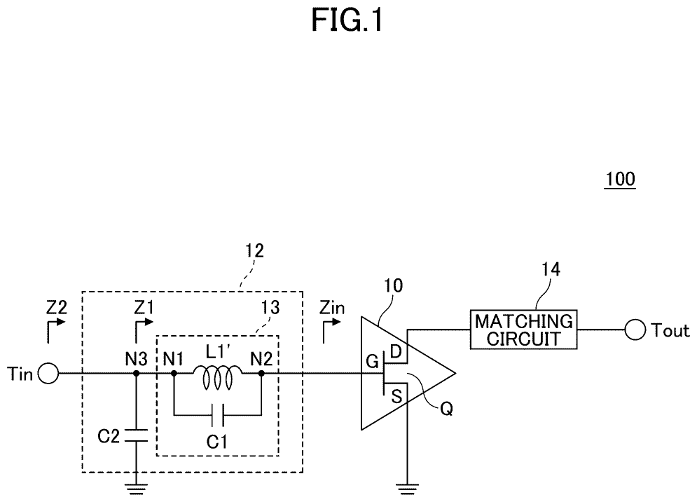

FIG. 1 is a circuit diagram of an amplifier circuit according to a first embodiment. As shown in FIG. 1, an amplifier circuit 100 of the first embodiment includes an amplifier 10 and matching circuits 12 and 14.

The amplifier 10 includes a transistor Q. The transistor Q is, for example, a field effect transistor (FET), and includes a source S, a drain D, and a gate G. The source S is electrically connected to a reference potential terminal, such as a ground terminal, and is short-circuited. The gate G is electrically connected to an input terminal Tin through the matching circuit 12. The drain D is electrically connected to an output terminal Tout through the matching circuit 14.

The transistor Q is, for example, a gallium nitride high electron mobility transistor (GaN HEMT) or a laterally diffused metal oxide semiconductor (LDMOS).

A high frequency signal is input to the input terminal Tin. The matching circuit 12 matches impedance Z2 viewed from the input terminal Tin toward the matching circuit 12 with the impedance Zin viewed from the matching circuit 12 toward the gate G. The amplifier 10 amplifies the high frequency signal input from the input terminal Tin to the gate G through the matching circuit 12, and outputs the amplified high frequency signal to the drain D. The matching circuit 14 matches impedance viewed from the drain D toward the matching circuit 14 with impedance viewed from the matching circuit 14 toward the output terminal Tout. The output terminal Tout is amplified by the amplifier 10 and outputs the high frequency signal.

The matching circuit 12 includes a parallel resonance circuit 13 and a capacitor C2. The parallel resonance circuit 13 includes an inductor L1′ and a capacitor C1 connected in parallel with each other between nodes N1 and N2, and each of the inductor L1′ and the capacitor C1 has both ends electrically connected to the nodes N1 and N2. The node N1 is electrically connected to the input terminal Tin, and the node N2 is electrically connected to the gate G. The capacitor C2 is shunt-connected to a node N3 between the input terminal Tin and the node N1. The impedance viewed from the node N3 toward the amplifier 10 is Z1. When the amplifier circuit 100 is used as a power amplifier for base stations of mobile communications, the center frequency of the operating band is, for example, 0.5 GHz to 20 GHz.

### COMPARATIVE EXAMPLE

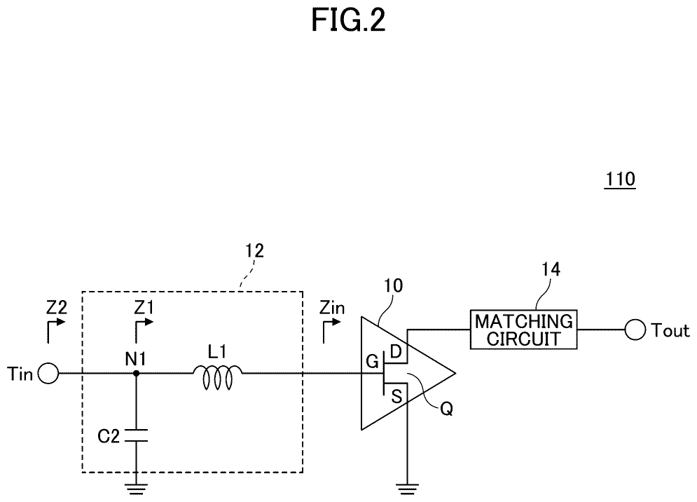

FIG. 2 is a circuit diagram of an amplifier circuit according to a comparative example. As shown in FIG. 2, the matching circuit 12 of an amplifier circuit 110 of the comparative example does not have the capacitor C1. The other circuit configuration is the same as that of FIG. 1 of the first embodiment.

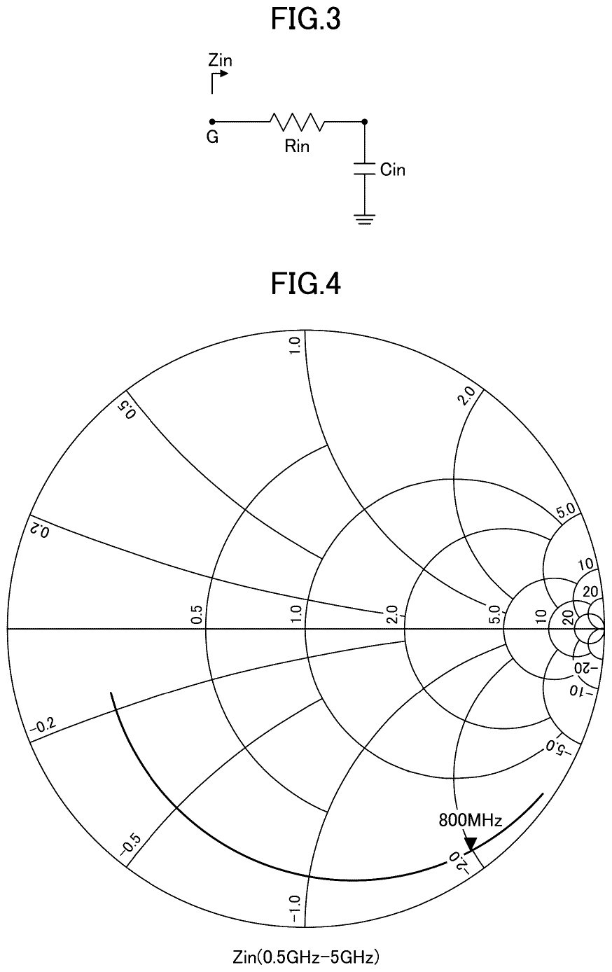

FIG. 3 is an equivalent circuit of the impedance Zin of the amplifier 10. As shown in FIG. 3, the impedance Zin in FIGS. 1 and 2 is equivalently represented by a resistor Rin and a capacitor Cin. The resistor Rin and the capacitor Cin are connected in series between the gate G and a reference potential. One end of the resistor Rin is connected to the gate G, and one end of the capacitor Cin is connected to the reference potential.

When the maximum output of the amplifier 10 is increased, the transistor Q is made larger. Thus, the resistance value of the resistor Rin is reduced. A case where the transistor Q is a GaN HEMT, the center frequency of the operating band of the amplifier circuit 110 is 800 MHz, and the maximum power is 350 W, will be described. In this case, the resistance value of the resistor Rin is about 0.2Ω, and the capacitance of the capacitor Cin is about 100 pF.

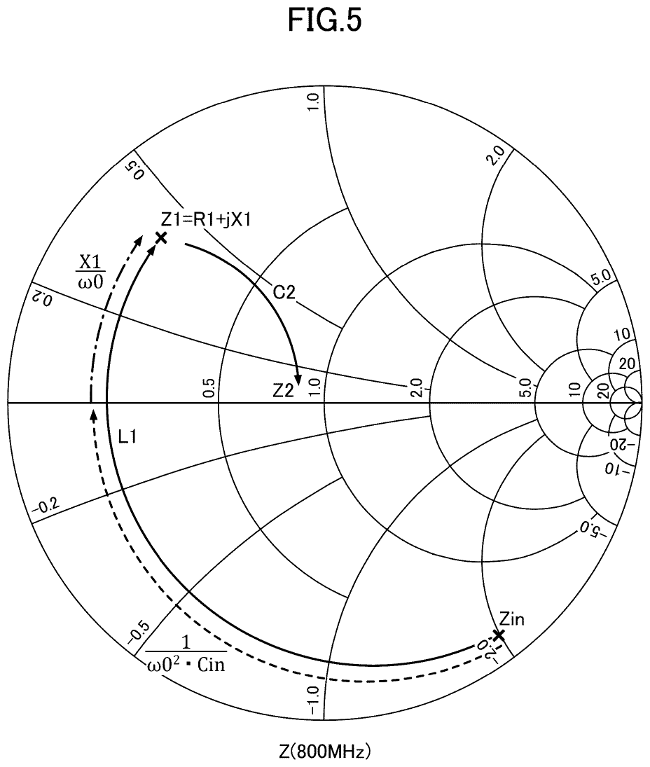

FIG. 4 is a Smith chart showing the impedance Zin. In FIG. 4, the reference impedance is set to 1Ω, the frequency is scanned from 0.5 GHz to 5 GHz, and the point of 800 MHz is indicated by a lower triangle. The position of the impedance Zin at 800 MHz on the Smith chart is close to an outer periphery because the resistance value of the resistor Rin is small. When the amplifier 10 is mounted on a package, the impedance of 0.2Ω is too low to be handled by a mounting substrate. Thus, the matching circuit for increasing the impedance is provided in the package.

FIG. 5 is a Smith chart for illustrating impedance matching by the matching circuit 12. As shown in FIG. 5, an inductor L1 rotates the phase of the impedance Zin clockwise to convert the impedance Zin into the impedance Z1. The capacitor C2 converts the impedance Z1 into the impedance Z2 on the real axis. This makes it possible to convert the impedance Zin into the impedance Z2 that is easy to handle in the mounting substrate. When the impedance Z1 is equal to R1 plus jX1 (j is an imaginary unit), the inductance of the inductor L1 is expressed by the following Equation 1.

$$L 1 = \frac{1}{ω {0}^{2} \cdot Cin} + \frac{X 1}{ω 0} \qquad [ Equation 1 ]$$

Here, ω0 is an angular frequency at a center frequency f0 of the operating band, and Cin is a capacitance of the capacitor Cin. A reactance X1 is a value determined in order to convert the impedance Z1 into the desired impedance Z2 by the shunt-connected capacitor C2. When an angular frequency ω0 is small, L1 increases by a reciprocal of a square of 70. Thus, the inductance of the inductor L1 is changed depending on the operation frequency.

For example, when L1 is about 0.6 nH and C2 is about 300 pF, the impedance Zin at 800 MHz can be converted into the impedance Z2 of 2Ω on the real axis. However, in order to set the inductor L1 to 0.6 nH, a long or large inductor is used. For example, when L1 is to be set to 0.6 nH by using a bonding wire, the length of the bonding wire is 4 mm as an example.

### Description of First Embodiment

In the first embodiment, the inductor L1 in FIG. 2 is replaced with the parallel resonance circuit 13 as shown in FIG. 1. When the inductance of the inductor L1′ is denoted by L1′ and the capacitance of the capacitor C1 is denoted by C1, a resonant angular frequency or of the parallel resonance circuit 13 is expressed by Equation 2.

$$ω r = \frac{1}{\sqrt{L {1}^{′} \cdot C 1}} = m \cdot ω0 \qquad [ Equation 2 ]$$

To replace the parallel resonance circuit 13 with the inductor L1 of FIG. 2, the parallel resonance circuit 13 should be inductive at a center frequency. Thus, ωr is larger than ω0, and m>1. In order to make the reactance of the parallel resonance circuit 13 at the angular frequency 70 equal to the reactance ω0·L1 of the inductor L1 in FIG. 2, the following Equation 3 must be satisfied.

$$ω D \cdot L 1 = ω0 \cdot \frac{L {1}^{′}}{1 - \frac{ω {0}^{2}}{ω {r}^{2}}} \qquad [ Equation 3 ]$$

L1′/L1 is derived from Equation 2 and Equation 3, and when m>1, Equation 4 is derived.

$$\frac{L {1}^{′}}{L 1} = \frac{{m}^{2} - 1}{{m}^{2}} < 1 \qquad [ Equation 4 ]$$

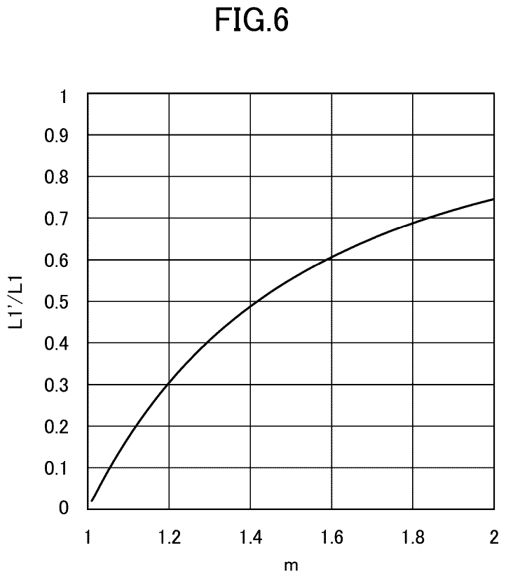

FIG. 6 is a diagram showing L1′/L1 with respect to m. As shown in FIG. 6 and Equation 4, when m>1, L1′/L1 is smaller than 1. Thus, when the inductor L1 in FIG. 2 is replaced by the parallel resonance circuit 13, the inductance of the inductor L1′ can be reduced. Thus, the amplifier circuit 100 can be downsized.

### Second Embodiment

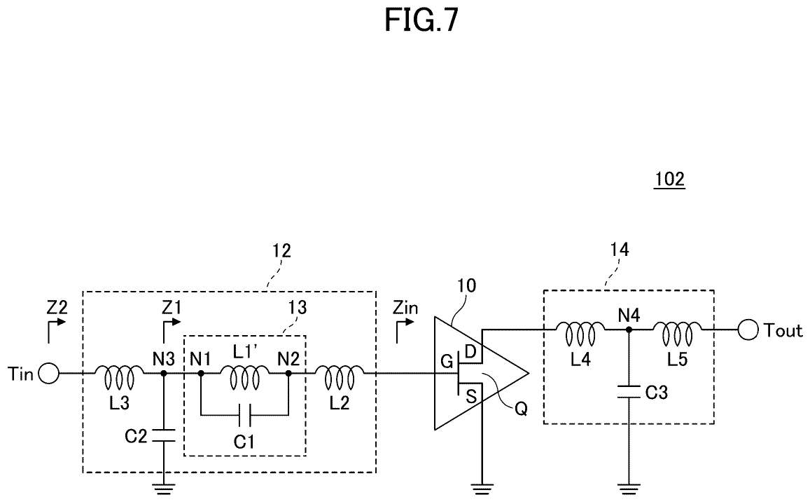

The second embodiment is an example in which a bonding wire is used as the inductor L1′. FIG. 7 is a circuit diagram of an amplifier circuit according to the second embodiment. As shown in FIG. 7, in an amplifier circuit 102 of the second embodiment, the matching circuit 12 includes inductors L2 and L3 in addition to the inductor L1′ and the parallel resonance circuit 13. The inductor L2 is electrically connected between the node N2 and the gate G. Both ends of the inductor L2 are electrically connected to the node N2 and the gate G. The inductor L3 is electrically connected between the input terminal Tin and the node N3.

The matching circuit 14 includes an inductor L4, an inductor L5 and a capacitor C3. The inductor L4 and the inductor L5 are connected in series between the drain D and the output terminal Tout. The capacitor C3 is shunt-connected to a node N4 between the inductors L4 and L5.

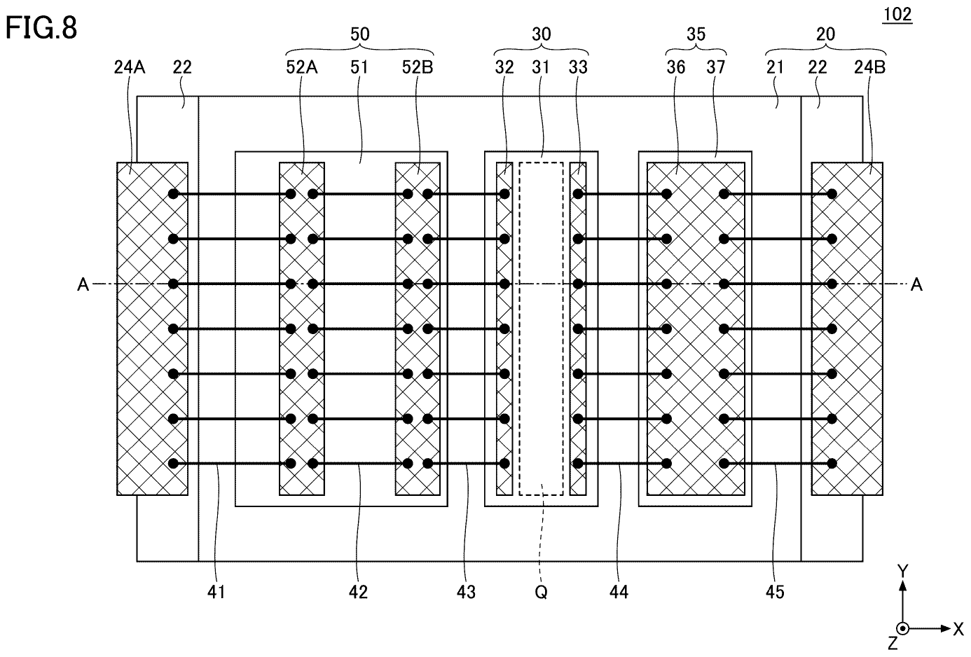

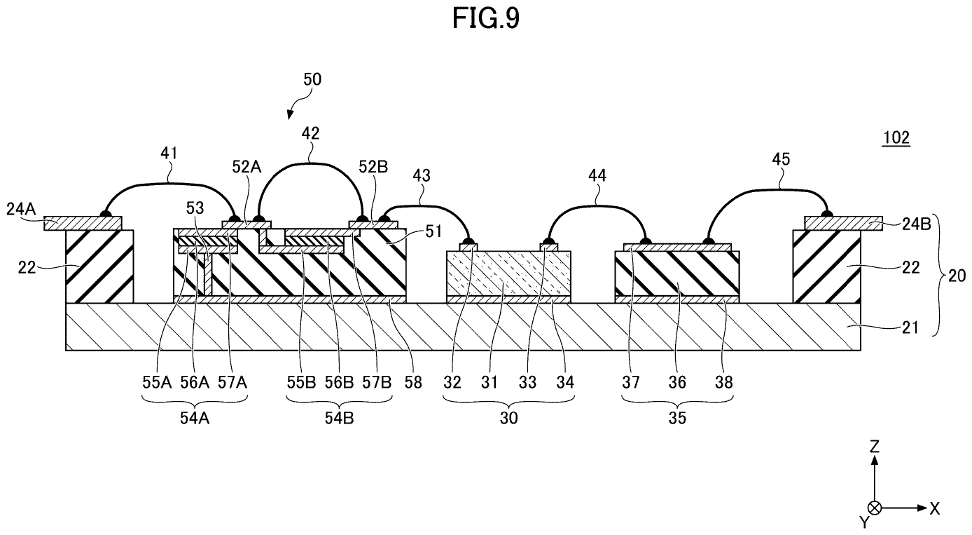

FIG. 8 is a plan view of an amplifier circuit according to a second embodiment. FIG. 9 is an A-A cross-sectional view of FIG. 8. A thickness direction of a base 21 is defined as a Z direction, a direction from an input terminal 24A toward an output terminal 24B is defined as an X direction, and a direction orthogonal to the X direction and the Z direction is defined as a Y direction.

As shown in FIGS. 8 and 9, the amplifier circuit 102 according to the second embodiment includes a package 20, a semiconductor chip 30, and passive components 35 and 50. The package 20 includes the base 21, a dielectric layer 22, the input terminal 24A, and the output terminal 24B. At least a +Z surface of the base 21 is a conductor. The base 21 may be a metal plate in which, for example, a copper layer, a molybdenum layer, and a copper layer are laminated. The base 21 functions as a reference potential terminal to which a reference potential such as a ground potential is supplied.

The semiconductor chip 30 and the passive components 35 and 50 are mounted on the base 21 with, for example, a conductive bonding layer interposed therebetween. The dielectric layer 22 is provided on the base 21 so as to sandwich the semiconductor chip 30 and the passive components 35 and 50 in the X direction. The dielectric layer 22 is an insulating layer made of, for example, ceramics or resin. The dielectric layer 22 may be a frame body surrounding the semiconductor chip 30 and the passive components 35 and 50. A lid for sealing the semiconductor chip 30 may be bonded onto the frame. The input terminal 24A and the output terminal 24B are provided on the dielectric layer 22. The input terminal 24A and the output terminal 24B are metal layers such as copper layers or gold layers. The input terminal 24A and the output terminal 24B correspond to the input terminal Tin and the output terminal Tout, respectively.

The semiconductor chip 30 includes a semiconductor substrate 31, pads 32 and 33, an electrode 34, and the transistor Q (i.e., the amplifier 10). The pads 32 and 33 are provided on an upper surface of the semiconductor substrate 31. The electrode 34 is provided on a lower surface of the semiconductor substrate 31. The pads 32 and 33 and the electrode 34 are electrically connected to the gate G, the drain D, and the source S of the transistor Q, respectively. When the transistor Q is a GaN HEMT, the semiconductor substrate 31 is, for example, a silicon carbide substrate or a sapphire substrate. When the transistor Q is LDMOS, the semiconductor substrate 31 is, for example, a silicon substrate. The pads 32 and 33 and the electrode 34 are metal layers such as gold layers or copper layers.

The passive component 50 includes a substrate 51, pads 52A and 52B, an electrode 58, a via 53, and capacitors 54A and 54B. The pads 52A and 52B are provided on an upper surface of the substrate 51. The electrode 58 is provided on a lower surface of the substrate 51. The capacitors 54A and 54B are provided on the substrate 51. The capacitor 54A includes a lower electrode 55A, a dielectric layer 56A, and an upper electrode 57A. The dielectric layer 56A is sandwiched between the lower electrode 55A and the upper electrode 57A. The lower electrode 55A is electrically connected to the electrode 58 through the via 53. The upper electrode 57A is electrically connected to the pad 52A. The capacitor 54B includes a lower electrode 55B, a dielectric layer 56B, and an upper electrode 57B. The dielectric layer 56B is sandwiched between the lower electrode 55B and the upper electrode 57B. The lower electrode 55B is electrically connected to the pad 52A. The upper electrode 57B is electrically connected to the pad 52B.

The passive component 50 is, for example, an integrated passive device (IPD). The substrate 51 is, for example, a semiconductor substrate such as a silicon substrate or an insulating substrate such as an alumina substrate. The pads 52A and 52B, the via 53, the lower electrodes 55A and 55B, the upper electrodes 57A and 57B, and the electrode 58 are metal layers such as gold layers or copper layers. The dielectric layers 56A and 56B are, for example, alumina layers or barium titanate layers. The capacitors 54A and 54B correspond to the capacitors C2 and C1, respectively.

The passive component 35 includes a dielectric substrate 36 and electrodes 37 and 38. The electrode 37 is provided on an upper surface of the dielectric substrate 36. The electrode 38 is provided on a lower surface of the dielectric substrate 36. The dielectric substrate 36 is, for example, an alumina substrate or a barium titanate substrate. The electrodes 37 and 38 are metal layers such as gold layers or copper layers. The dielectric substrate 36 and the electrodes 37 and 38 correspond to the capacitor C3, with the electrodes 37 and 38 sandwiching the dielectric substrate 36.

Bonding wires 41 electrically connect the input terminal 24A and the pad 52A. Bonding wires 42 electrically connect the pad 52A and the pad 52B. Bonding wires 43 electrically connect the pad 52B and the pad 32. Bonding wires 44 electrically connect the pad 33 and the electrode 37. Bonding wires 45 electrically connect the electrode 37 and the output terminal 24B. The bonding wires 41 to 45 are thin metal wires such as gold wires or aluminum wires. The bonding wires 41 to 45 correspond to the inductors L3, L1′, L2, L4 and L5, respectively.

### (Simulation)

Simulations were performed for the comparative example and the second embodiment. The transistor Q is a GaN HEMT, the maximum power is 350 W, and a center frequency is 800 MHz. The matching circuit 14 is set so that the impedances match.

Table 1 shows simulation conditions.

TABLE 1

| m | L1′/L1 | fr [MHz] | L1 [nH] | L1′ [nH] | L2 [nH] | C1 [pF] |
|---|---|---|---|---|---|---|
| ∞ | 1 | — | 0.56 | — | — | — |
| 1.25 | 0.36 | 1000 | — | 0.181 | 0.0023 | 145 |
| 1.125 | 0.21 | 900 | — | 0.114 | 0.0023 | 282 |

A case of m=∞ corresponds to a comparative example, and L1′/L1 is 1. L1 was 0.56 nH. The cases of m=1.25 and m=1.125 correspond to the second embodiment. When m=1.25, L1′/L1=0.36, and a resonance frequency fr of the parallel resonance circuit 13 is about 1000 MHz. When m=1.125, L1′/L1=0.21, and the resonance frequency fr is 900 MHz. L1, L1′, C1, and C2 were adjusted so that the bandwidth was maximized at each m. The inductor L1′ was assumed to have 44 bonding wires connected in parallel between the pads 52A and 52B.

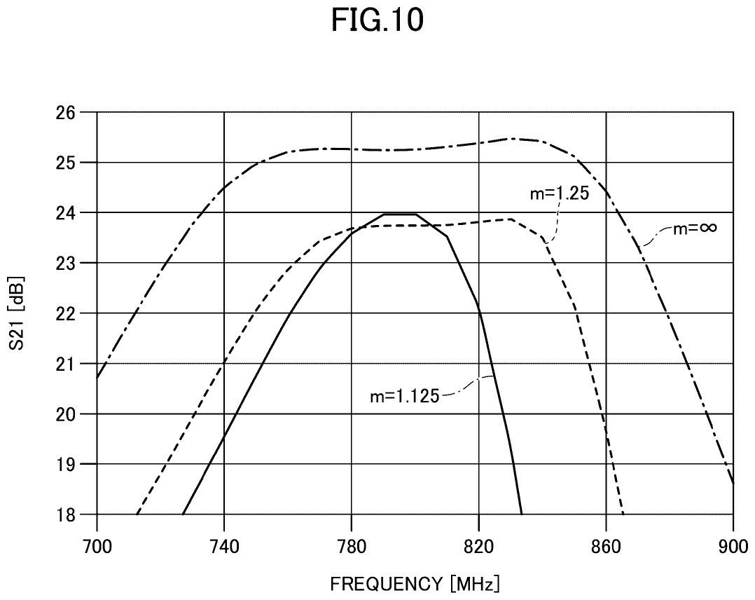

FIG. 10 shows S21 with respect to frequency, which is obtained from 2-port S parameters simulated with the input terminal Tin as port 1 and the output terminal Tout as port 2. S21 corresponds to the gain of the amplifier circuit 102.

As shown in FIG. 10, when m=∞, the bandwidth is about 120 MHz. As shown in FIG. 10, when m=1.25 and 1.125, the bandwidth is about 80 MHz and about 40 MHz, respectively. As m becomes close to 1, the bandwidth decreases. This is because the resonance frequency fr of the parallel resonance circuit 13 is close to 800 MHz.

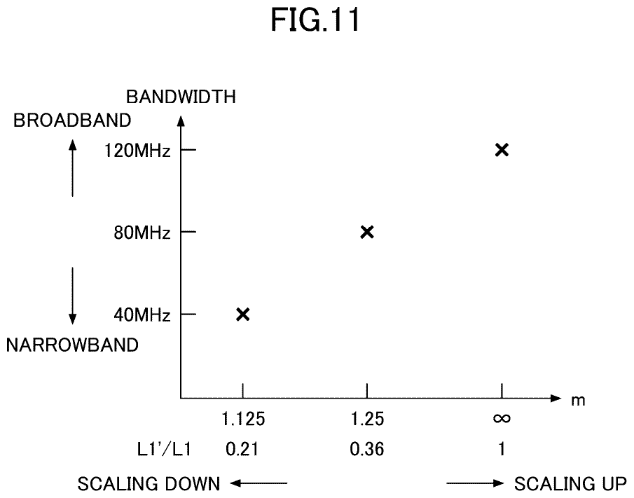

FIG. 11 is a schematic diagram showing bandwidth with respect to m, and is a diagram summarizing the results of FIG. 10. As shown in FIG. 11, when m becomes close to 1, L1′/L1 becomes small, and the inductor L1′ can be small. Thus, the amplifier circuit can be downsized. However, when m becomes close to 1, the bandwidth becomes small, and it is difficult to have a wide operating band.

According to the first embodiment and the second embodiment, the matching circuit 12 includes the inductor L1′ (first inductor) and the capacitor C1 (first capacitor) connected in parallel between the input terminal Tin and the amplifier 10. Each of the inductor L1′ and the capacitor C1 has both ends electrically connected to the input terminal Tin and the amplifier 10. The resonance frequency fr of the parallel resonance circuit 13 having the inductor L1′ and the capacitor C1 is at a frequency of 1.9 times or less of the center frequency f0 of the operating band in the amplifier 10. That is, m≤1.9. As a result, as shown in FIG. 6, the inductance of the inductor L1′ can be 0.7 times or less that of the inductor L1 of the comparative example shown in FIG. 2. Thus, the amplifier circuit can be downsized.

When the amplifier circuit 102 is used in a base station for mobile communications, the most frequently used band is the 2 GHz band. Thus, a case where the package 20 used in the 2 GHz band is used for the amplifier circuit 102 of the low band is considered. According to Equation 1, at the frequency of 2 GHz×1/N, the inductance of the inductor L1 is between N times and N² times as large as that at 2 GHz. Thus, when an amplifier circuit having the center frequency f0 of 2/N GHz is mounted on the package 20 used in the 2 GHz band, it is sufficient that L1′/L1 is set to about 1/N to 1/N². The bands of 1.5 GHz and 0.8 GHz are also often used in base stations for mobile communications. For example, when the center frequency f0 is 1.5 GHz, N is equal to 4/3, and L1′/L1 is 1/(4/3)² to 1/(4/3), so 0.56 to 0.75. As shown in FIG. 6, when the center frequency f0 is 1.5 GHz, m is 1.5 to 1.9. For example, when the center frequency f0 is 0.8 GHz, N is equal to 2.5, and L1′/L1 is 1/(2.5) 2 to 1/(2.5), so 0.16 to 0.4. As shown in FIG. 6, when the center frequency f0 is 0.8 GHz, m is 1.15 to 1.3.

As described above, from the viewpoint of downsizing, the resonance frequency fr may be 1.8 times or less, 1.6 times or less, or 1.5 times or less of the center frequency f0. When the resonance frequency fr is close to the center frequency f0, the bandwidth is narrowed as shown in FIG. 11. From this viewpoint, the resonance frequency fr may be 1.1 times or more, or 1.2 times or more, of the center frequency f0.

The parallel resonance circuit 13 may be provided in the matching circuit 14. In this case, the inductor L1′ and the capacitor C1 are connected in parallel between the amplifier 10 and the output terminal Tout. When the impedance Zin of the amplifier 10 is small, the inductor L1 of the matching circuit 12 becomes large. Thus, the amplifier circuit can be downsized by providing the parallel resonance circuit 13 in the matching circuit 12.

When the impedance Z2 can be a desired resistance value on the real axis by the parallel resonance circuit 13, the capacitor C2 does not have to be provided. By providing the capacitor C2 (second capacitor) shunt-connected to the node N3 between the input terminal Tin and a circuit including the inductor L1′ and the capacitor C1, the impedance Zin having a low resistance component can be converted into the impedance Z2 having a high resistance component as shown in FIG. 5.

As shown in FIGS. 8 and 9, the inductor L1′ includes the bonding wire 42 (first bonding wire) having a first end electrically connected to a first end of the capacitor C1 and a second end electrically connected to a second end of the capacitor C1. When the inductor L1 in the comparative example is formed using a bonding wire, the length becomes 4 mm as an example. In this case, the package 20 becomes large. When the size of the package 20 is reduced to be 6 mm or less, the passive component 35 cannot be mounted in the package 20. Thus, as in the second embodiment, the capacitor C1 is connected to the inductor L1′ in parallel, so that the bonding wire 42 can be shortened. Thus, the package 20 can be small, and the amplifier circuit can be downsized.

The passive component 50 is mounted on the base 21, and includes the capacitor C1 (capacitor 54B in FIG. 9), the pad 52A (first pad) electrically connected to a first end of the capacitor C1, and the pad 52B (second pad) electrically connected to the second end of the capacitor C1. A first end of the bonding wire 42 is bonded to the pad 52A, and the second end of the bonding wire 42 is bonded to the pad 52B. In this manner, by bonding both ends of the bonding wire 42 to the passive component 50 having the capacitor C1, the parallel resonance circuit 13 can be formed in and on the passive component 50. Thus, the planar size of the package 20 can be reduced.

The semiconductor chip 30 includes the amplifier 10 and the pad 32 (third pad) electrically connected to the amplifier 10. The bonding wire 43 (second bonding wire) has a first end electrically connected to the pad 52B and a second end electrically connected to the pad 32. This enables the amplifier 10 and the parallel resonance circuit 13 to be electrically connected to each other.

The passive component 50 includes the capacitor C2 (capacitor 54A in FIG. 9) shunt-connected to the pad 52A. This allows the capacitors C1 and C2 and the inductor L1′ to be formed in and on the passive component 50. Thus, the planar size of the package 20 can be reduced.

The amplifier 10 has the transistor Q. The inductor L1′ and the capacitor C1 are connected in parallel between the input terminal Tin and the gate G of the transistor Q. Each of the inductor L1′ and the capacitor C1 has both ends electrically connected to the input terminal Tin and the gate G. Even when the resistor Rin of the gate G is low and the inductor L1 is large in the comparative example, the inductor L1′ can be reduced, and the amplifier circuit can be downsized.

The resistor Rin of the gate G is low when the output power of the amplifier circuit is large. From this point of view, the parallel resonance circuit 13 can be used when the practical maximum power of the amplifier circuit is 50 W or more, 100 W or more, or 200 W or more.

The inductor L1 becomes long when the center frequency f0 is low, as shown in Equation 1. From this viewpoint, the parallel resonance circuit 13 can be used when the center frequency f0 of the operating band is 2.2 GHz or less, 1.5 GHz or less, or 1 GHz or less.

The embodiments disclosed herein are to be considered in all respects as illustrative and not restrictive. The scope of the present disclosure is defined by the appended claims rather than by the foregoing description, and all changes that come within the meaning and range of equivalency of the claims are intended to be embraced therein.

What is claimed is:

1. An amplifier circuit comprising:
an input terminal to which a high frequency signal is to be input;
an amplifier configured to amplify the high frequency signal;
an output terminal configured to output the high frequency signal amplified by the amplifier; and
a matching circuit including a first inductor and a first capacitor connected in parallel between the input terminal and the amplifier or between the amplifier and the output terminal,
wherein a resonance frequency of the first inductor with the first capacitor is 1.9 times or less of a center frequency of an operating band of the amplifier.

2. The amplifier circuit according to claim 1,
wherein the resonance frequency is 1.1 times or more of the center frequency.

3. The amplifier circuit according to claim 1,
wherein the resonance frequency is 1.6 times or less of the center frequency.

4. The amplifier circuit according to claim 1,
wherein the matching circuit is electrically connected between the input terminal and the amplifier, and includes both ends electrically connected to the input terminal and the amplifier.

5. The amplifier circuit according to claim 4, further comprising:
a second capacitor shunt-connected to a node between the input terminal and a circuit including the first inductor and the first capacitor.

6. The amplifier circuit according to claim 1,
wherein the first inductor includes a first bonding wire including a first end electrically connected to a first end of the first capacitor and a second end electrically connected to a second end of the first capacitor.

7. The amplifier circuit according to claim 6, further comprising:
a base; and
a passive component mounted on the base and including the first capacitor, a first pad, and a second pad, the first pad being electrically connected to a first end of the first capacitor, and the second pad being electrically connected to a second end of the first capacitor,
wherein the first end of the first bonding wire is bonded to the first pad, and the second end of the first bonding wire is bonded to the second pad.

8. The amplifier circuit according to claim 7, further comprising:
a semiconductor chip mounted on the base and including the amplifier and a third pad electrically connected to the amplifier; and
a second bonding wire including a first end electrically connected to the second pad and a second end electrically connected to the third pad.

9. The amplifier circuit according to claim 7,
wherein the passive component includes a second capacitor shunt-connected to the first pad.

10. The amplifier circuit according to claim 1,
wherein the amplifier includes a transistor, and
wherein the first inductor and the first capacitor are connected in parallel between the input terminal and a gate of the transistor.
